(19) United States
(12) Patent Application Publication
(10) Pub. No.: US 2006/0292805 A1
(43) Pub. Date: Dec. 28, 2006

(54) Semiconductor device

(75) Inventors: Keiko Kawamura, Yokohama-shi (JP); Shingo Sato, Kawasaki-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ku (JP)

(21) Appl. No.: 11/447,114

(22) Filed: Jun. 6, 2006

(30) Foreign Application Priority Data
Jun. 27, 2005 (JP) 2005-187046

(51) Int. Cl. H01L 21/336; H01L 29/76

(52) U.S. Cl. 438/292; 438/268; 257/288

(57) ABSTRACT

A semiconductor device is provided, which includes a first main electrode region having an upper main surface and a lower main surface; a drift layer of a first conductivity type formed on the upper main surface of the first main electrode region; a base layer of a second conductivity type formed on the drift layer; a second main electrode region of the first conductivity type formed on the base layer; a trench formed through the second main electrode region to the drift layer; a gate insulation film formed on an inner wall of the trench; and a gate electrode buried in the trench with the gate insulation film interposed therebetween, wherein the drift layer includes a graded region close to the first main electrode region, the graded region having band gap decreasing from the base layer toward the first main electrode region.

### CROSS REFERENCE TO RELATED APPLICATION

This application is based on and claims the benefit of prior Japanese Patent Application No. 2005-187046, filed on Jun. 27, 2005, the entire contents of which are incorporated herein by reference.

### BACKGROUND OF THE INVENTION

1. Field of the Invention

The present invention relates to a semiconductor device.

2. Description of the Related Art

In recent years, fine patterning is required in a power device such as a MOSFET, and lowering on-resistances is strongly desired over the whole semiconductor system including the device.

A trench gate type MOS transistor in the case of p-type has been formed in the art as follows. First, a p⁺-type drain layer is formed in a semiconductor substrate and a p⁻-type epitaxial layer is formed on the drain layer. In the p⁻-type epitaxial layer, a p⁻-type drift layer, an n-type base layer, and a p⁺-type source region are formed in turn from the p⁺-type drain layer. In the p⁻-type epitaxial layer, trenches are formed through the p⁺-type source region to a depth reaching the p⁻-type drift layer. A gate insulator is formed over the inner wall of the trench. A trench gate electrode composed of polysilicon is buried in the trench with the gate insulator interposed therebetween. An interlayer insulator is deposited over the trench gate electrode. Contact holes are opened through the interlayer insulator at certain locations. A source electrode composed of metal is formed over the interlayer insulator. The source electrode is commonly brought into contact with part of the surface of the p⁺-type source region and part of the surface of the n-type base layer through the contact hole. (See JP-A 2004-241413, for example).

In the MOS transistor thus configured, the resistance in the p⁻-type epitaxial layer occupies a large proportion in the overall resistance. Thinning the thickness of the p⁻-type epitaxial layer may be considered as a method of lowering the on-resistance. A thinned thickness of the p⁻-type drift layer, however, causes a reduction in breakdown voltage across source-drain. An impurity may be considered to diffuse from the p⁺-type drain layer in the semiconductor substrate into the p⁻-type drift layer. Accordingly, it is required to form the drift layer with a certain thickness or thicker.

### SUMMARY OF THE INVENTION

In an aspect of the present invention provides a semiconductor device, which includes a first main electrode region having an upper main surface and a lower main surface a drift layer of a first conductivity type formed on the upper main surface of the first main electrode region; a base layer of a second conductivity type formed on the drift layer; a second main electrode region of the first conductivity type formed on the base layer; a trench formed through the second main electrode region to the drift layer; a gate insulation film formed on an inner wall of the trench; and a gate electrode buried in the trench with the gate insulation film interposed therebetween, wherein the drift layer includes a graded region close to the first main electrode region, the graded region having band gap decreasing from the base layer toward the first main electrode region.

In another aspect of the present invention provides a semiconductor device, which includes a first main electrode region having an upper main surface and a lower main surface a drift layer of the first conductivity type formed on the upper main surface of the first main electrode region; a base region of a second conductivity type formed in an upper surface portion of the drift layer; a second main electrode region of the first conductivity type formed in an upper surface portion of the base region; a gate insulation film formed along the drift layer, the base region and the second main electrode region; and a gate electrode formed on the gate insulation film, the gate electrode opposing the drift layer, the base layer and the second main electrode region, wherein the drift layer includes a graded region close to the first main electrode region, the graded region having band gap decreasing from the base region toward the first main electrode region.

### BRIEF DESCRIPTION OF THE DRAWINGS

FIG. 1 is a cross-sectional view of a trench gate type MOS transistor according to a first embodiment of the present invention;

FIG. 2 is a plan view seen from the direction of the arrow A-A′ in FIG. 1;

FIG. 3 is a cross-sectional view illustrative of a process step of manufacturing the trench gate type MOS transistor;

FIG. 4 is a cross-sectional view illustrative of a process step of manufacturing the trench gate type MOS transistor;

FIG. 5 shows energy bands in the trench gate type MOS transistor according to the first embodiment;

FIG. 6 is a cross-sectional view of a trench IGBT according to a second embodiment of the present invention;

FIG. 7 shows energy bands in the trench IGBT according to the second embodiment;

FIG. 8 is a cross-sectional view of a planar gate type MOS transistor according to a third embodiment of the present invention; and

FIG. 9 is a cross-sectional view of a planar IGBT according to a fourth embodiment of the present invention.

### DETAILED DESCRIPTION OF THE INVENTION

Embodiments of the present invention will now be described with reference to the drawings.

[First Embodiment]

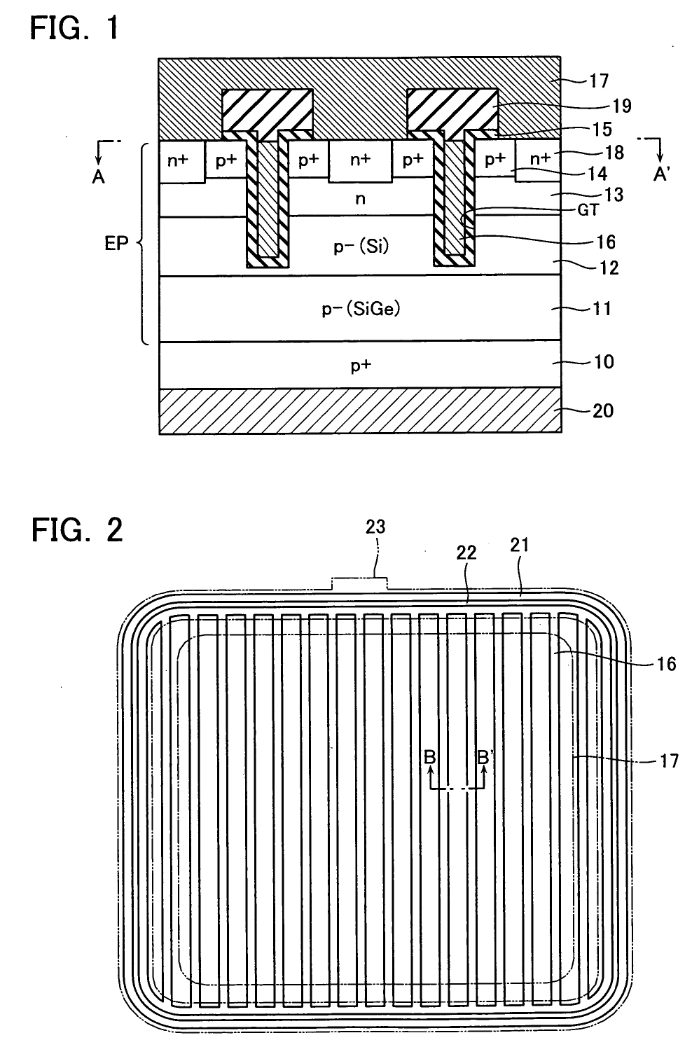

FIGS. 1 and 2 show a structure of a trench gate type MOS transistor according to a first embodiment of the present invention. FIG. 1 is cross-sectional view taken along B-B′ in FIG. 2, and FIG. 2 is a plan view seen from the direction of the arrow A-A′ in FIG. 1.

As shown in FIG. 1, this trench gate type MOS transistor includes a p⁺-type drain layer 10, and a first drift layer 11 and a second drift layer 12 formed in turn on the p⁺-type drain layer 10 by epitaxial growth. As detailed later, the first drift layer 11 is composed of SiGe and formed as a graded layer having such Ge concentrations that exhibit the maximum in a plane adjacent to the p⁺-type drain layer 10 and near the composition ratio of Si alone as approaching the second drift layer 12. An n-type base layer 13 is formed in the second drift layer 12, and a p⁺-type source region 14 is formed in the n-type base layer 13. Gate trenches GT are formed in the second drift layer 12 through the p⁺-type source region 14 and the n-type base layer 13. A trench gate electrode 16 is buried in the gate trench GT with a gate insulator 15 interposed therebetween.

As shown in FIG. 2, the gate electrode 16 extends in a direction perpendicular to the page of FIG. 1. In a plane in parallel with the page, the gate electrodes 16 are arranged in parallel at a certain interval.

The gate electrodes 16 are covered in an interlayer insulator 19. The interlayer insulator 19 is removed from locations between adjacent gate electrodes 16 and, on the locations, contact regions 18 are formed extending through the p⁺-type source region 14 to the n-type base layer 13. A source electrode 17 covers the interlayer insulator 19 and establishes connection with the p⁺-type source region 14 and the contact region 18. A drain electrode 20 is formed on the p⁺-type drain layer 10. Both ends of the gate electrode 16 shown in FIG. 2 are connected to an outer annular polysilicon layer 21. The outer annular polysilicon layer 21 is connected to a gate electrode pad 23 in the upper layer above the interlayer insulator 19 via a contact hole 22 passing through the interlayer insulator 19 (the gate electrode pad 23 is isolated from the source electrode 17).

The following description is given to a method of manufacturing the trench gate type MOS thus configured.

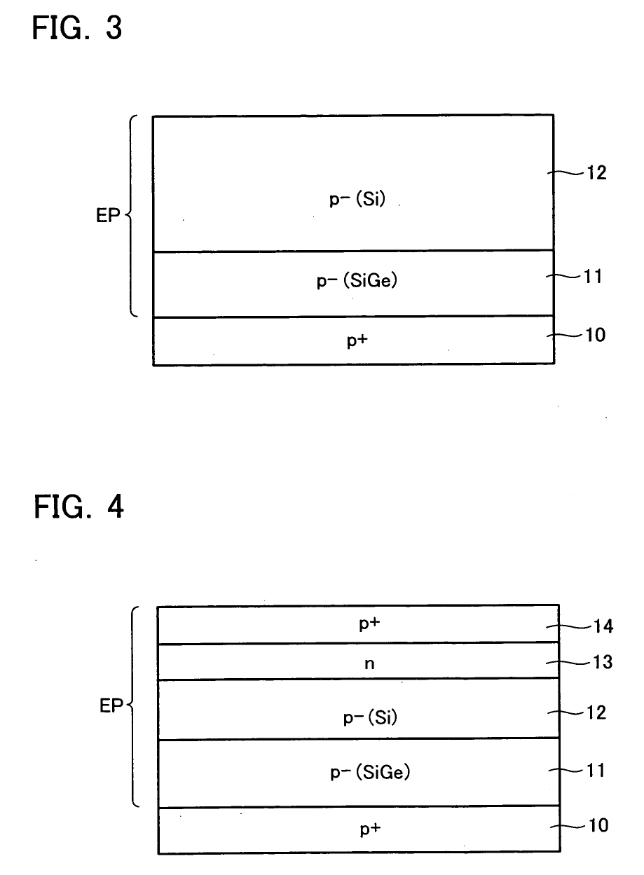

As shown in FIG. 3, the high-concentration boron-doped p⁺-type drain layer 10 is a p-type silicon substrate itself or additionally formed on a p-type silicon substrate. A low-concentration boron-doped p⁻-type epitaxial layer EP is formed on the p⁺-type drain layer 10 by epitaxial growth.

The p⁻-type epitaxial layer EP is formed as follows. First, the first drift layer 11 composed of SiGe is formed by epitaxial growth on the surface of the p⁺-type drain layer 10, and then the second drift layer 12 composed of Si is formed on the first drift layer 11. The first drift layer 11 and the second drift layer 12 are low-concentration boron-doped. The first drift layer 11 is formed as a graded layer having such Ge concentrations that exhibit the maximum in a plane adjacent to the p⁺- type drain layer 10 and near the composition ratio of Si configuring the second drift layer 12 as approaching the second drift layer 12. The composition ratio becomes Si in a plane adjacent to the second drift layer 12.

In this case, the p⁻-type first drift layer 11 is formed of SiGe on the p⁺-type drain layer 10. Alternatively, a high-concentration boron-doped SiGe layer may be formed as part of the p⁺-type drain layer 10 on the p-type silicon substrate by epitaxial growth. Then, a layer of p⁻-type SiGe given a concentration distribution may be epitaxially grown as the first drift layer 11 on the SiGe layer. In this case, the Ge concentration distribution in SiGe may be varied from the high-concentration p-type SiGe layer. In a word, the graded layer having the varying Ge concentration distribution in SiGe has a layered structure containing part of the p⁺-type drain layer 10 and the first drift layer 11.

Next, as shown in FIG. 4, in the p⁻-type epitaxial layer, the phosphorous or arsenic-doped n-type base layer 13 is formed in the second drift layer 12, and the high-concentration boron-doped p⁺-type source region 14 is formed in the n-type base layer 13.

Further, in the p⁻-type epitaxial layer EP, the gate trenches GT are formed extending from the surface of the p⁺-type source region to a depth reaching the second drift layer 12. The gate insulator 15 is formed over the inner wall of the gate trench GT. The trench gate electrode 16 composed of impurity-doped polysilicon is buried and formed in the gate trench GT with the gate insulator 15 interposed therebetween.

Further, the contact regions 18 are formed extending from the surface of the p⁺-type source region 14 to a depth reaching some midpoint in the n-type base layer 13 by n-type selective diffusion. The p⁺-type source region 14 and the contact regions 18 are formed such that the source electrode 17 is brought into contact with n-type base layer 13. The interlayer insulator 19 is deposited over the trench gate electrode 16. Contact holes are opened through the interlayer insulator 19 at certain locations. The source electrode 17 composed of metal is formed over the interlayer insulator 19. The source electrode 17 is commonly brought into contact with part of the p⁺-type source region 14 and the contact region 18 as a contact of part of the n-type base layer 13 through the contact hole. And the drain electrode 20 is brought into contact with the p⁺-type drain layer 10.

Preferably, the bottom of the trench gate electrode 16 does not reach the first drift layer 11. Alternatively, it may reach the first drift layer 11 if the Ge concentration of the first drift layer 11 in contact with the bottom of the gate trenches GT is 5E20/cm³ or below for the following reason. Introduction of SiGe reduces the band gap in the first drift layer 11 and consequently prevents the breakdown electric field strength in the first drift layer 11 from lowering in the vicinity of the trench gate electrode. The first drift layer 11 of SiGe has a thickness with the Ge concentration of 5E20/cm³ or higher. Preferably, it has a thickness of 50 nm or above, which can prevent impurity diffusion from the p⁺-type drain layer 10 when the Ge concentration is 5E20/cm³. Preferably, it has a critical thickness of 5 μm or below, which can prevent lattice dislocation from occurring due to stresses when the Ge concentration is 5E20/cm³. The critical thickness of the SiGe layer can be determined almost based on the Ge concentration and the growth temperature in the same layer as reported (D. C. Houghton, J. Appl. Phys. 70(4), 1991, 2136-2151 and D. C. Houghton et al., Appl. Phys. Lett. 56(5), 1990, 460-462). The Ge concentration in the first drift layer 11 reaches the maximum at a plane adjacent to the p⁺-type drain layer 10. The maximum may be determined to have an optimal value depending on the transistor characteristic of the trench gate type MOS transistor according to this embodiment.

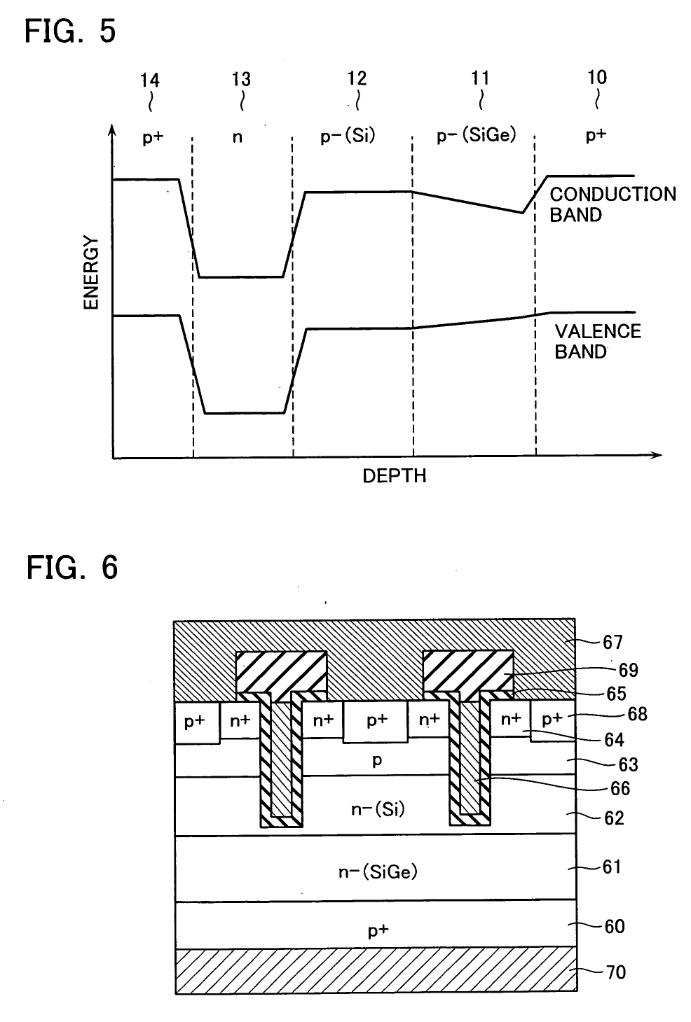

The trench gate type MOS transistor according to the first embodiment of the present invention has a structure of layered semiconductors as described above. The structure of layered semiconductors has energy bands as shown in FIG. 5 with the solid lines. The upper solid line represents an energy band in the conduction band and the lower solid line represents an energy band in the valence band. The longitudinal axis represents the energy potential of the trench gate type MOS transistor of this embodiment and the lateral axis represents the distance (depth) from the surface of the p⁺-type source region 14 to the p⁺-type drain layer 10.

As shown in FIG. 5, a SiGe layer is formed as the first drift layer in between the p⁺-type drain layer 10 and the second drift layer 12. SiGe is smaller in band gap than Si that configures the second drift layer 12. In this case, from the second drift layer 12 toward the p⁺-type drain layer 10, the Ge concentration is gradually increased, that is, the composition ratio of Ge is gradually increased. Therefore, the first drift layer 11 and the second drift layer 12 have variations in band gap as follows. The band gap gradually decreases from the second drift layer 12 toward the first drift layer 11. The band gap is not discontinued in between first drift layer 11 and the second drift layer 12. The band gap is discontinued only in between the first drift layer 11 and the p⁺-type drain layer 10. Therefore, it is possible in the first drift layer 11 and the second drift layer 12 to suppress the increase in on-resistance caused by the carrier accumulation/ stay effect due to the discontinuity of the band gap.

In the trench gate type MOS transistor thus configured, the first drift region composed of SiGe having a smaller band gap than that of Si is formed on the p⁺-type drain layer. This makes it possible to improve the mobility of holes between the p⁺-type drain layer and the second drift region, that is, between the p⁺-type source region and the p⁺-type drain layer. Therefore, it is possible to reduce the on-resistance of the trench gate type MOS transistor according to the first embodiment of the present invention. In addition, the Ge concentration in SiGe formed in the first drift layer is gradually increased from the second drift layer toward the p⁺-type drain layer. This makes it possible to eliminate the discontinuity of the band gap between the first drift layer and the second drift layer. Therefore, it is possible to suppress the increase in on-resistance caused by the carrier accumulation/stay effect due to the discontinuity of the band gap. In addition, the use of SiGe different from Si in between the p⁺-type drain layer and the second drift layer makes it possible to suppress the impurity diffusion from the p⁺-type drain layer. Accordingly, the thickness of the overall drift layer can be thinned and thus the on-resistance can be lowered without causing the impurity diffusion to degrade the resistance to the electric field breakdown.

In this embodiment, SiGe is used in the first drift layer though SiGeC having a smaller band gap than that of Si may be used instead. In this case, like this embodiment, the Ge concentration may be increased from the second drift layer toward the p⁺-type drain layer. SiGeC is more effective than SiGe to suppress the impurity diffusion from the p⁺-type drain layer. Accordingly, it is possible to further thin the thickness of the drain layer and lower the on-resistance. The p-type trench gate type MOS transistor is exemplified in this embodiment though the embodiment is not limited to the example but the same effect can be achieved in an n-type trench gate type MOS transistor with all conduction types inverted.

[Second Embodiment]

FIG. 6 is a cross-sectional view illustrative of a structure of a trench IGBT, which is a semiconductor device according to a second embodiment of the present invention.

Different from the first embodiment of the present invention, the trench gate type MOS transistor used in the first embodiment is changed to an IGBT. This embodiment is described by way of an n-channel IGBT.

As shown in FIG. 6, the IGBT of this embodiment is similar in configuration to that of the first embodiment and can be described with reference to FIG. 1 of the first embodiment. In this case, the p⁺-type drain layer 10 corresponds to a p⁺-type collector layer 60, the n-type base layer 13 to a p-type base layer 63, the p⁺-type source region 14 to an n⁺-type emitter region 64, the source electrode 17 to an emitter electrode 67, and the drain electrode 20 to a collector electrode 70.

The p⁺-type collector layer 60 is formed in the boron-doped p-type silicon substrate. On the p⁺-type collector layer 60, a first drift layer 61 composed of SiGe having the same concentration distribution as that of the first embodiment and a second drift layer 62 composed of Si are formed by epitaxial growth in a layered structure. Different from the first embodiment, the first drift layer 61 and the second drift layer 62 have a low-concentration phosphorous or arsenic-doped n-conduction type. The boron-doped p-type base layer 63 is formed on the surface of the second drift layer 62. The high-concentration phosphorous or arsenic-doped n⁺-type emitter region 64 is formed on the surface of the p-type base layer 63. Other descriptions of a gate insulator 65, trench gate electrodes 66, the emitter electrode 67, contact regions 68, an interlayer insulator 69 and the collector electrode 70 are similar to those in the first embodiment and are accordingly omitted herein.

Preferably, the bottom of the trench gate electrode 66 does not reach the first drift layer 61. Alternatively, it may reach the first drift layer 61 if the Ge concentration of the first drift layer 61 in contact with the bottom of the gate trenches GT is 5E20/cm³ or below for the following reason. Introduction of SiGe reduces the band gap in the first drift layer 61 and consequently prevents the breakdown electric field strength in the first drift layer 61 from lowering in the vicinity of the trench gate electrode. The first drift layer 61 of SiGe has a thickness with the Ge concentration of 5E20/cm³ or higher. Preferably, it has a thickness of 50 nm or above, which can prevent impurity diffusion from the p⁺-type collector layer 60 when the Ge concentration is 5E20/cm³. Preferably, it has a critical thickness of 5 μm or below, which can prevent lattice dislocation from occurring due to stresses when the Ge concentration is 5E20/cm³. The Ge concentration in the first drift layer 61 reaches the maximum at a plane adjacent to the p⁺-type collector layer 60. The maximum may be determined to have an optimal value depending on the transistor characteristic of the trench IGBT according to this embodiment.

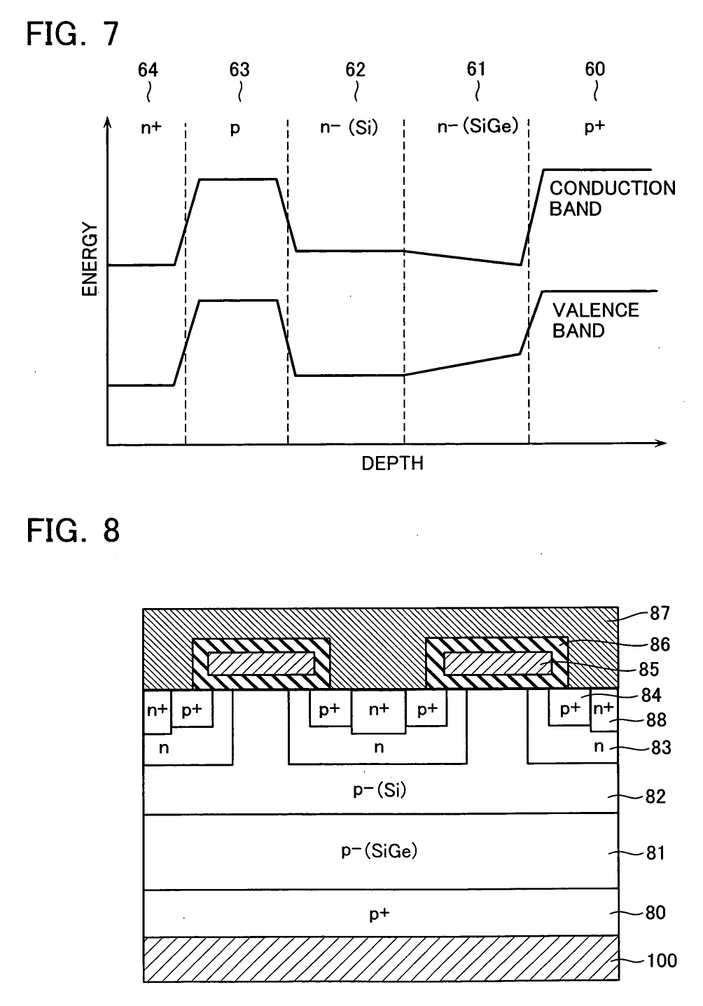

The trench IGBT according to the second embodiment of the present invention has a structure of layered semiconductors as described above. The structure of layered semiconductors has energy band s as shown in FIG. 7 with the solid lines. The upper solid line represents an energy band in the conduction band and the lower solid line represents an energy band in the valence band. The longitudinal axis represents the energy potential of the trench IGBT of this embodiment, and the lateral axis represents the distance from the surface of the n⁺-type emitter region 64 to the p⁺-type collector layer 60 of the trench IGBT of this embodiment.

In the IGBT of this embodiment thus configured, like the first embodiment, the first drift region composed of SiGe having a smaller band gap than that of Si is formed on the p⁺-type collector layer. This makes it possible to lower the saturation voltage that corresponds to the on-resistance in the IGBT according to this embodiment. In addition, the Ge concentration in SiGe formed in the first drift layer is gradually increased from the second drift layer toward the p⁺-type collector layer. This is effective to suppress the increase in saturation voltage caused by the carrier accumulation/stay effect due to the discontinuity of the band gap. In addition, the use of SiGe different from Si in between the p⁺-type collector layer and the second drift layer makes it possible to suppress the impurity diffusion from the p⁺-type collector layer. Accordingly, the thickness of the overall drift layer can be thinned and thus the saturation voltage can be lowered.

In this embodiment, SiGe is used in the first drift layer though SiGeC having a smaller band gap than that of Si may be used instead. In this case, like this embodiment, the Ge concentration may be increased from the second drift layer toward the p⁺-type collector layer. SiGeC is more effective than SiGe to suppress the impurity diffusion from the p⁺-type collector layer. Accordingly, it is possible to further thin the thickness of the drain layer and lower the saturation voltage.

[Third Embodiment]

FIG. 8 is a cross-sectional view illustrative of a structure of a planar gate type MOS transistor according to a third embodiment. Different from the first embodiment of the present invention, the trench gate type MOS transistor is changed to the planar gate type MOS transistor.

A high-concentration boron-doped p⁺-type drain layer 80 is formed in a substrate. On the p⁺-type drain layer 80, a first drift layer 81 and a second drift layer 82 both low-concentration boron-doped are formed by epitaxial growth. The first drift layer 81 is formed of SiGe and the second drift layer 82 is formed of Si. The first drift layer 81 includes a graded layer having Ge concentrations that decrease from the p⁺-type drain layer 80 toward the second drift layer 82. In the second drift layer 82, a phosphorous or arsenic-doped n-type base region 83 is formed by selective diffusion. In the base region 83, a high-concentration boron-doped p⁺-type source region 84 and a high-concentration phosphorous or arsenic-doped contact region 88 are formed by selective diffusion. On the second drift layer 82 with the n-type base region 83 and the p⁺-type source region 84 formed therein, a gate electrode 85 is formed and covered in a gate insulator 86. A source electrode 87 is formed in contact with the p⁺-type source region 84 and the n-type base region 83. And a drain electrode 100 is formed in contact with the p⁺-type drain layer 80.

Even in such the planar gate type MOS transistor, the first drift region 81 composed of SiGe having a smaller band gap than that of Si is formed on the p⁺-type drain layer 80. This makes it possible to improve the mobility of holes between the p⁺-type source region and the p⁺-type drain layer. This embodiment is described using the p-type MOS transistor though the same effect can be achieved using an n-type MOS transistor.

[Fourth Embodiment]

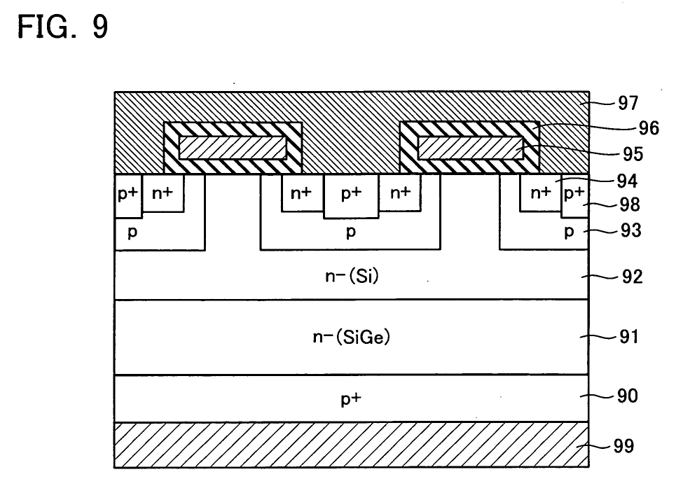

FIG. 9 is a cross-sectional view illustrative of a structure of an IGBT according to a fourth embodiment of the present invention. Different from the third embodiment, the trench IGBT is changed to the planar IGBT.

A high-concentration boron-doped p⁺-type collector layer 90 is formed on a substrate. On the p⁺-type collector layer 90, a phosphorous or arsenic-doped first drift layer 91 and a second drift layer 92 are formed by epitaxial growth. The first drift layer 91 is formed of SiGe and the second drift layer 92 composed is formed of Si. The first drift layer 91 includes a graded layer having Ge concentrations that decrease from the p⁺-type collector layer 90 toward the second drift layer 92. In the second drift layer 92, a boron-doped p-type base region 93 is formed by selective diffusion. In the base region 93, a high-concentration phosphorous or arsenic-doped n⁺-type emitter region 94 and a high-concentration boron-doped contact region 98 are formed by selective diffusion. On the second drift layer 92 with the p-type base region 93 and the n⁺-type source region 94 formed therein, agate electrode 95 is formed and covered in a gate insulator 96. Further, an emitter electrode 97 is formed in contact with the n⁺-type source region 94 and the p-type base region 93. And a collector electrode 99 is formed in contact with the p⁺-type collector layer 90.

Even in such the planar IGBT, the first drift layer 91 composed of SiGe having a smaller band gap than that of Si is formed on the p⁺-type collector layer 90 to lower the saturation voltage. In addition, the use of SiGe different from Si in between the p⁺-type collector layer 90 and the second drift layer 92 makes it possible to suppress the impurity diffusion from the p⁺-type collector layer. Accordingly, the thickness of the overall drift layer can be thinned and thus the saturation voltage can be lowered. This embodiment is described using the n-channel IGBT though the same effect can be achieved using a p-channel IGBT.

The present invention is not limited to the above-described embodiments but rather can be modified variously without departing from the gist of the invention.

What is claimed is:

1. A semiconductor device, comprising:
a first main electrode region having an upper main surface and a lower main surface;
a drift layer of a first conductivity type formed on the upper main surface of the first main electrode region;
a base layer of a second conductivity type formed on the drift layer;
a second main electrode region of the first conductivity type formed on the base layer;
a trench formed through the second main electrode region to the drift layer;
a gate insulation film formed on an inner wall of the trench; and
a gate electrode buried in the trench with the gate insulation film interposed therebetween, wherein the drift layer includes a graded region close to the first main electrode region, the graded region having band gap decreasing from the base layer toward the first main electrode region.

2. The semiconductor device according to claim 1, wherein the first main electrode region is of the first conductivity type.

3. The semiconductor device according to claim 2, wherein the drift layer comprises a first drift layer formed on the upper main surface of the first main electrode region, and a second drift layer formed on the first drift layer, the first drift layer includes the graded region.

4. The semiconductor device according to claim 3, wherein the first drift layer is formed of SiGe or SiGeC, and wherein the second drift layer is formed of Si.

5. The semiconductor device according to claim 4, wherein the first drift layer has Ge concentrations lowering from the first main electrode region toward the second drift layer.

6. The semiconductor device according to claim 5, wherein the first drift layer has a thickness of from 50 nm to 5 μm with Ge concentrations of 5E20/cm³ or above.

7. The semiconductor device according to claim 6, wherein the bottom of the trench locates in the second drift layer.

8. The semiconductor device according to claim 6, wherein the bottom of the trench reaches the first drift layer, and wherein the first drift layer in contact with the bottom of the trench has a Ge concentration of 5E20/cm³ or below.

9. The semiconductor device according to claim 1, wherein the first main electrode region is of the second conductivity type.

10. The semiconductor device according to claim 9, wherein the drift layer comprises a first drift layer formed on the upper main surface of the first main electrode region, and a second drift layer formed on the first drift layer, the first drift layer includes the graded region.

11. The semiconductor device according to claim 10, wherein the first drift layer is formed of SiGe or SiGeC, and wherein the second drift layer is formed of Si.

12. The semiconductor device according to claim 11, wherein the first drift layer has Ge concentrations lowering from the first main electrode region toward the second drift layer.

13. The semiconductor device according to claim 12, wherein the first drift layer has a thickness of from 50 nm to 5 μm with Ge concentrations of 5E20/cm³ or above.

14. The semiconductor device according to claim 13, wherein the bottom of the trench locates in the second drift layer.

15. The semiconductor device according to claim 13, wherein the bottom of the trench reaches the first drift layer, and wherein the first drift layer has a Ge concentration of 5E20/cm³ or below at the bottom of the trench.

16. A semiconductor device, comprising:
a first main electrode region having an upper main surface and a lower main surface;
a drift layer of the first conductivity type formed on the upper main surface of the first main electrode region;
a base region of a second conductivity type formed in an upper surface portion of the drift layer;
a second main electrode region of the first conductivity type formed in an upper surface portion of the base region;
a gate insulation film formed along the drift layer, the base region and the second main electrode region; and
a gate electrode formed on the gate insulation film, the gate electrode opposing the drift layer, the base layer and the second main electrode region, wherein the drift layer includes a graded region close to the first main electrode region, the graded region having band gap decreasing from the base region toward the first main electrode region.

17. The semiconductor device according to claim 16, wherein the first main electrode region is of the first conductivity type.

18. the semiconductor device according to claim 16, wherein the first main electrode region is of the second conductivity type.

19. The semiconductor device according to claim 16, wherein the drift layer comprises a first drift layer formed on the upper main surface of the first main electrode region, and a second drift layer formed on the first drift layer, the first drift layer includes the graded region.

20. The semiconductor device according to claim 19, wherein the first drift layer is formed of SiGe or SiGeC, and wherein the second drift layer is formed of Si.
